(19) United States
(12) Patent Application Publication
(10) Pub. No.: US 2018/0123523 A1
(43) Pub. Date: May 3, 2018

(54) LOW GAIN LINEARIZATION FOR HIGH SIGNAL-TO-NOISE RATIO

(71) Applicant: QUALCOMM Incorporated, San Diego, CA (US)

(72) Inventors: Sasha VUJCIC, San Diego, CA (US); Mehmet UZUNKOL, San Diego, CA (US); Kevin Hsi Huai WANG, San Diego, CA (US)

(21) Appl. No.: 15/447,718

(22) Filed: Mar. 2, 2017

Related U.S. Application Data
(60) Provisional application No. 62/413,904, filed on Oct. 27, 2016.

(51) Int. Cl. H03F 1/26; H03F 1/22; H03F 3/24; H03F 3/19; H03F 1/56

(52) U.S. Cl. CPC H03F 1/26; H03F 1/223; H03F 3/245; H03F 3/19; H03F 2200/387; H03F 2200/294; H03F 2200/451; H03F 2200/135; H03F 1/565

(57) ABSTRACT

A low noise amplifier (LNA) includes a transconductance device coupled to a cascode transistor. The LNA also includes a resistor capacitor (RC) feedback branch. The RC feedback branch includes a first resistor, a capacitor and a first switch. The RC feedback branch is fed back around the transconductance device and is coupled between a drain of either the cascode transistor or the transconductance device and a gate of the transconductance device.

### CROSS-REFERENCE TO RELATED APPLICATION

The present application claims the benefit of U.S. Provisional Patent Application No. 62/413,904, filed on Oct. 27, 2016, and titled “LOW GAIN LINEARIZATION FOR HIGH SIGNAL-TO-NOISE RATIO,” the disclosure of which is expressly incorporated by reference herein in its entirety.

### BACKGROUND

### Field

The present disclosure relates generally to electronics, and more specifically to amplifiers.

### Background

A wireless device (e.g., a cellular phone or a smartphone) in a wireless communication system may transmit and receive data for two-way communication. The wireless device may include a transmitter for data transmission and a receiver for data reception. For data transmission, the transmitter may modulate a local oscillator (LO) signal with data to obtain a modulated signal, amplify the modulated signal to obtain an output radio frequency (RF) signal having the proper transmit power level, and transmit the output RF signal via an antenna to a base station. For data reception, the receiver may obtain a received RF signal via the antenna and may amplify and process the received RF signal to recover data sent by the base station.

A wireless device may include amplifiers of different types for different purposes. For example, a wireless device may include a low noise amplifier (LNA) in a receiver, a power amplifier (PA) in a transmitter, and a variable gain amplifier (VGA) in the receiver and/or the transmitter. An amplifier (e.g., an LNA) may be used to have a configurable gain in order to handle different signal conditions.

With the advent of more complex data schemes, such as 256 quadrature amplitude modulation (QAM), higher signal-to-noise (SNR) ratio is desirable to achieve the maximum throughput. For high SNR operation, LNAs are typically configured in “low gain” mode, and the LNAs dominant degradation to SNR are intermodulation (IMD) products, which are characterized by third order input intercept point (IIP3). As SNR specifications, and therefore low gain IIP3 specifications become more difficult, LNA design may be more challenging. It may be desirable to provide configurable gain while achieving good performance and low power consumption for the amplifier.

### SUMMARY

In an aspect of the present disclosure, a low noise amplifier (LNA) is presented. The LNA includes a transconductance device coupled to a cascode transistor. The LNA also includes a resistor capacitor (RC) feedback branch. The RC feedback branch includes a first resistor, a capacitor and a first switch. The RC feedback branch is fed back around the transconductance device and is coupled between a drain of either the cascode transistor or the transconductance device and a gate of the transconductance device.

In another aspect of the present disclosure, a method is presented. The method includes amplifying a radio frequency (RF) input signal with a gain transistor to produce an amplified signal. The method also includes selectively coupling a feedback branch around the gain transistor. The feedback branch is coupled between either a drain of a cascode transistor or the gain transistor and a gate of the gain transistor.

In yet another aspect of the present disclosure, a low noise amplifier is presented. The low noise amplifier includes means for amplifying a radio frequency input signal to produce an amplified signal. The low noise amplifier also includes means for selectively coupling a feedback branch around the amplifying means. The feedback branch is coupled between a drain of a first device and a gate of the amplifying means.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates a wireless device communicating with wireless systems.

FIG. 2 illustrates a block diagram of the wireless device in FIG. 1.

FIG. 3 is a schematic diagram of a low noise amplifier (LNA) with low gain linearization for high SNR in accordance with aspects of the present disclosure.

FIG. 4 is a schematic diagram of an exemplary low noise amplifier (LNA) in accordance with aspects of the present disclosure.

FIG. 5 is a schematic diagram of an exemplary low noise amplifier (LNA) with feedforward cancellation in accordance with aspects of the present disclosure.

FIG. 6A is a schematic diagram of an exemplary low noise amplifier (LNA) with feedforward cancellation and an RC feedback branch in accordance with aspects of the present disclosure.

FIG. 6B is a schematic diagram of an exemplary low noise amplifier (LNA) with multiple outputs in accordance with aspects of the present disclosure.

FIG. 6C is a schematic diagram of an exemplary low noise amplifier (LNA) with multiple inputs in accordance with aspects of the present disclosure.

FIG. 7 is a flow diagram illustrating an exemplary method in accordance with aspects of the present disclosure.

FIG. 8 is a block diagram showing an exemplary wireless communication system 800 in which an aspect of the disclosure may be advantageously employed.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

The term “couple” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches.

Amplifiers with a configurable feedback path including a resistor capacitor (RC) shunt branch for low gain operation is disclosed. These amplifiers can provide configurable gain while achieving good performance (e.g., improved IIP3 and S11 matching) in low gain mode while maintaining sensitivity (high gain mode) performance. These amplifiers may be used for various electronic devices such as wireless communication devices.

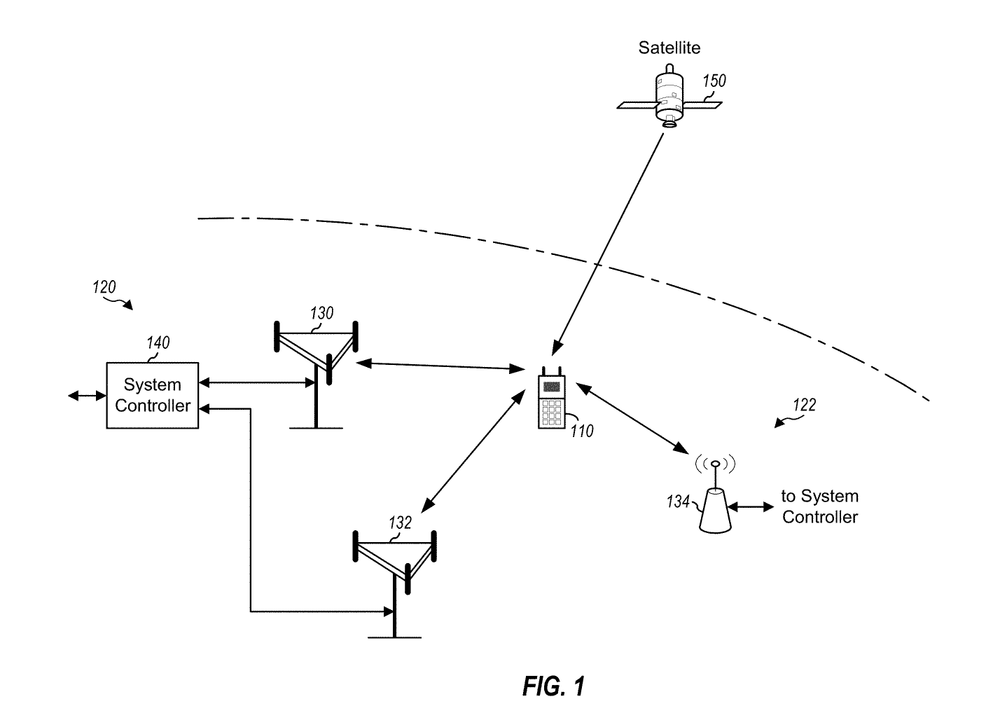

FIG. 1 illustrates a wireless device 110 communicating with wireless communication systems 120 and 122. Each wireless system may be a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), CDMA 1×, time division synchronous CDMA (TD-SCDMA), or some other version of CDMA. For simplicity, FIG. 1 shows the wireless system 120 including two base stations 130 and 132 and one system controller 140, and the wireless system 122 including one base station 134. In general, a wireless system may include any number of base stations and any set of network entities. A base station may also be referred to as a Node B, an evolved Node B (eNB), an access point, etc.

The wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. The wireless device 110 may communicate with the wireless system 120 and/or 122. The wireless device 110 may also receive signals from broadcast stations, signals from satellites (e.g., a satellite 150) in one or more global navigation satellite systems (GNSS), etc. The wireless device 110 may support one or more radio technologies for wireless communication such as LTE, WCDMA, CDMA 1×, TD-SCDMA, GSM, 802.11, etc.

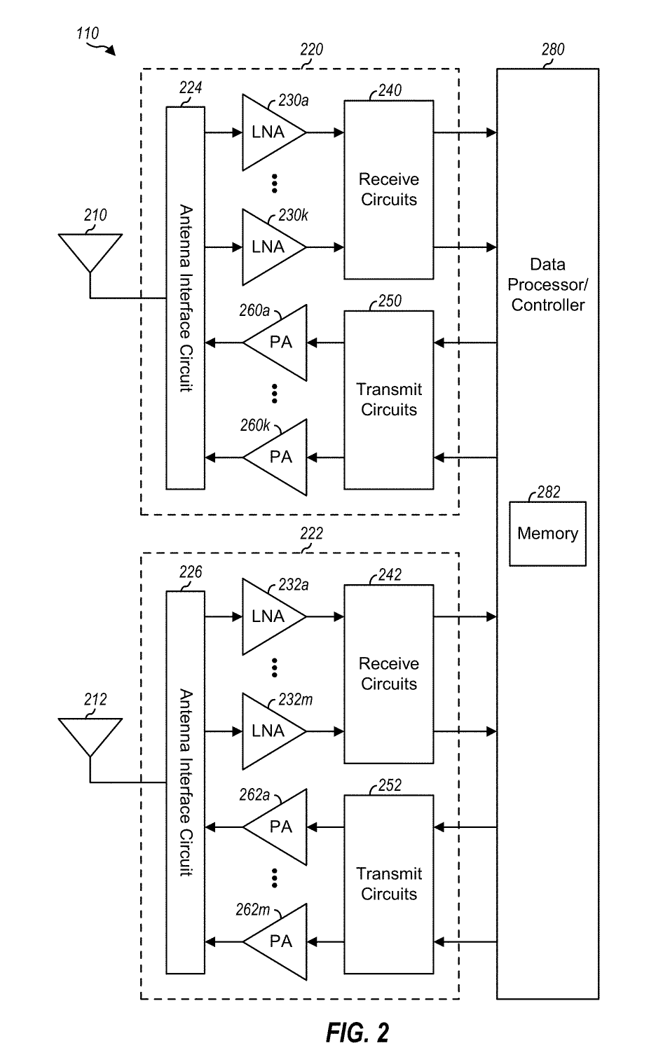

FIG. 2 illustrates a block diagram of an exemplary design of the wireless device 110 in FIG. 1. In this exemplary design, the wireless device 110 includes a transceiver 220 coupled to a primary antenna 210, a transceiver 222 coupled to a secondary antenna 212, and a data processor/controller 280. The transceiver 220 includes an antenna interface circuit 224, multiple (K) LNAs 230a to 230k, receive circuits 240, transmit circuits 250, and multiple (K) power amplifiers (PAs) 260a to 260k. The transceiver 222 includes an antenna interface circuit 226, multiple (M) LNAs 232a to 232m, receive circuits 242, transmit circuits 252, and multiple (M) PAs 262a to 262m. Transceivers 220 and 222 may support multiple frequency bands, carrier aggregation, multiple radio technologies, multiple wireless systems, receive diversity, transmit diversity, MIMO transmission from multiple transmit antennas to multiple receive antennas, etc., or any combination thereof.

For data reception, the antenna 210 receives signals from base stations and/or other transmitter stations and provides a received RF signal to antenna interface circuit 224. The antenna interface circuit 224 provides one or more input RF signals to one or more selected LNAs 230. The antenna interface circuit 224 may include switches, duplexers, diplexers, transmit filters, receive filters, matching circuits, directional couplers, etc. Each selected LNA 230 amplifies its input RF signal and provides one or more amplified RF signals to the receive circuits 240. The receive circuits 240 downconvert each amplified RF signal from RF to baseband, filter and amplify the downconverted signal, and provide an input baseband signal to a data processor 280. Receive circuits 240 may include mixers, filters, amplifiers, matching circuits, oscillators, LO generators, phase locked loops (PLLs), etc.

For data transmission, the data processor 280 processes (e.g., encodes and modulates) data to be transmitted and provides one or more output baseband signals to the transmit circuits 250. The transmit circuits 250 amplify, filter, and upconvert each output baseband signal from baseband to RF and provide a modulated signal to a selected PA 260. The transmit circuits 250 may include amplifiers, filters, mixers, matching circuits, oscillators, LO generators, PLLs, etc. Each selected PA 260 amplifies its modulated signal and provides an output RF signal having the proper transmit power level. The output RF signal from each selected PA 260 is routed through an antenna interface circuit 224 and transmitted via the antenna 210.

LNAs 232, receive circuits 242, transmit circuits 252, and PAs 262 within the transceiver 222 may operate in a similar manner as the LNAs 230, receive circuits 240, transmit circuits 250, and PAs 260 within the transceiver 220. The transceivers 220 and 222 may include other circuits not shown in FIG. 2. All or a portion of the transceivers 220 and 222 may be implemented on one or more analog integrated circuits (ICs), RF ICs (RFICs), mixed-signal ICs, etc. For example, the LNAs 230 and receive circuits 240 may be implemented on one module, which may be an RFIC, etc. The circuits in the transceivers 220 and 222 may also be implemented in other manners.

The data processor/controller 280 may perform various functions for the wireless device 110. For example, the data processor 280 may perform processing for data being received via the receiver circuits 240 and 242 and data being transmitted via the transmit circuits 250 and 252. The controller 280 may control the operation of various circuits within the transceivers 220 and 222. A memory 282 may store program codes and data for the data processor/controller 280. The data processor/controller 280 may be implemented on one or more application specific integrated circuits (ASICs) and/or other ICs.

FIG. 2 shows an exemplary design of the wireless device 110 with two transceivers 220 and 222 coupled to two antennas 210 and 212. In general, a wireless device may include any number of transceivers for any number of antennas. Each transceiver may include any number of LNAs and any number of PAs to support any number of frequency bands, any number of wireless systems, any number of radio technologies, etc.

### Low Gain Linearization for High SNR

With the advent of more complex data schemes, such as 256 quadrature amplitude modulation (QAM), signal-to-noise (SNR) ratio increases with throughput. For high SNR operation, low noise amplifiers (LNAs) are typically configured in “low gain” mode, and the LNAs dominant degradation to SNR are intermodulation (IMD) products, which are characterized by third order input intercept point (IIP3). As SNR specifications, and therefore low gain IIP3 specifications, become more stringent, LNA design becomes more challenging. Accordingly, aspects of the present disclosure are directed to a low noise amplifier (LNA) with low gain linearization for high SNR.

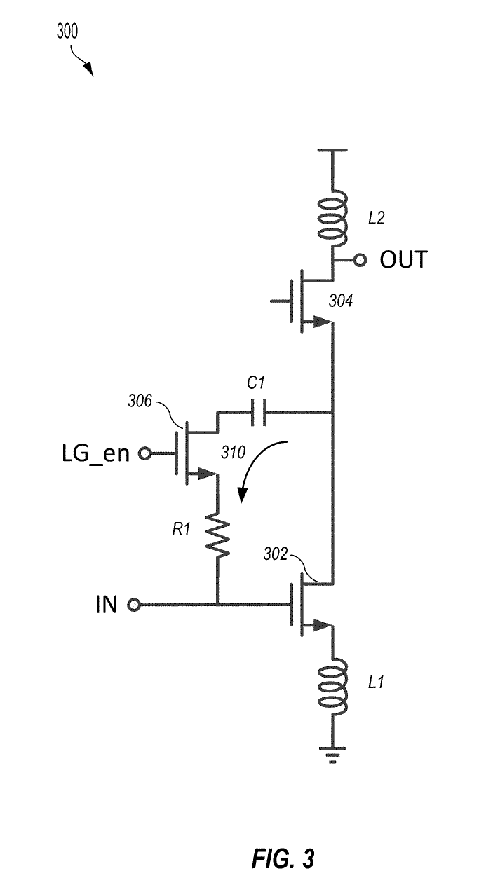

FIG. 3 is a schematic diagram of an LNA 300 with low gain linearization for high SNR in accordance with aspects of the present disclosure. The LNA 300 includes a gain transistor 302, a cascode transistor 304 and a resistor capacitor (RC) feedback branch 310. The RC feedback branch 310 includes a feedback transistor 306 (which may also be referred to as “switch 310”) coupled in series between a resistor R1 and a capacitor C1. The LNA also includes inductors L1 and L2. Inductor L1 may be included for impedance matching and may also enable the LNA 300 to obtain good dynamic range and achieve high sensitivity with low power consumption. L2 may comprise a primary coil of a load circuit (not shown).

As shown in FIG. 3, the RC feedback branch 310 is coupled between an input node IN at the gate of the gain transistor 302 and a node between the source of the cascode transistor 304 and the drain of the gain transistor 302. A control signal LG_enable (LG_en) is supplied to the gate of the feedback transistor 306. The control signal LG_enable may be used to enable or disable the RC feedback branch 310.

An input signal may be received via an input node (IN) of the LNA 300. In one exemplary aspect, the input signal may comprise an RF signal. The RF signal may include one or more desired signals as well as one or more interfering signals. A desired signal may comprise a transmitted signal to be received by a wireless device. An interfering signal may be a transmitted signal not intended to be received by the wireless device. The input RF signal may include a jammer, which is an interfering signal having a much larger amplitude than that of a desired signal and located close in frequency to the desired signal. Non-linearity of the LNA 300 may result in the jammer causing intermodulation distortion (IMD). The IMD or intermodulation products may overlap a desired signal in frequency and may act as additional noise that may adversely impact reception of the desired signal.

The LNA 300 may support multiple gain modes in order to handle different signal conditions. The multiple gain modes may include a high gain mode (sensitivity mode) and a low gain mode. The LNA 300 may operate in the high gain mode and provide a desired high gain when the desired signal is at the specified input power level for high gain mode and the LNA's linearity performance (e.g., IIP3) is not as significant as noise performance (e.g., noise figure (NF)) in determining whether the receiver (Rx) is meeting signal to noise ratio (SNR) specifications. The LNA 300 may operate in a low gain mode and provide a lower gain when the desired signal is at the specified input power level for low gain and the LNA's linearity performance (e.g., IIP3) is more significant than the noise performance (e.g., NF) in determining whether the receiver is meeting SNR specifications. The LNA 300 may have a lower gain in the low gain mode than in the high gain mode. By way of non-limiting example only, the low gain mode may be associated with a gain of 6 to 9 decibels (dB) lower than a gain associated with the high gain mode. The lower gain in the low gain mode may help a receiver meet linearity requirements in the presence of a jammer.

The RC feedback branch 310 may be enabled or disabled based on a mode of operation of the LNA. For example, when the LNA 300 is operating in a high gain mode, the RC feedback branch 310 may be disabled via the feedback transistor 306 under the control of control signal LG_en. In some aspects, the RC feedback branch may be disabled in a sensitivity mode, for example, to avoid degrading the noise factor, by controlling the feedback transistor to be off.

On the other hand, when the LNA is operating in a low gain mode, the RC feedback branch may be enabled via the feedback transistor 306 under the control of control signal LG_en. Advantageously, by incorporating the RC feedback branch 310 around a transconductance device (e.g., gain transistor 302), the linearity of the transconductance device (gain transistor 302) may be improved and in turn the IIP3 may also be improved. The linearity of the LNA 300 may be examined via the transconductance leaving the LNA of the feedback (gm3,fb) which is given by:

$${g}_{m 3 , fb} = \frac{{g}_{m 3} ( 1 + T ) - 2 {fg}_{m 2}}{{( 1 + T )}^{5}} \qquad ( 1 )$$

where gₘ₃ is the third order transconductance of the LNA 300, gₙ₂ is the second order transconductance of the LNA 300, T is the loop gain, and ƒ is the feedback transfer function. The feedback transfer function ƒ is the gain from the input of the feedback (drain of the gm device) to the output of the feedback (gate of the gm device). As shown in equation 1, the gm3 of the LNA is reduced by the loop gain.

Impedance matching (e.g., S11 matching) may also be improved. This is because the effective shunt resistance of the LNA 300 is lowered by the loop gain T of the feedback (e.g., RC feedback branch 310).

Accordingly, in high gain mode operation, the LNA 300 may receive an input signal (e.g., a voltage) at the input node IN. When the control signal LG_en controls the feedback transistor to be OFF, the RC feedback branch 310 is disabled. The input signal is supplied to the gain transistor 302. The gain transistor 302 amplifies the input signal and produces a current (I) at the drain with a gain corresponding to the device transconductance (gm). This current I is provided to the cascode transistor 304 and output via an output node OUT. The voltage at the output may be given by the LNA current * overall impedance at the output node.

In low gain mode operation, the LNA 300 may receive an input signal (e.g., a voltage) at the input node IN. When the control signal LG_en controls the feedback transistor to be ON, the RC feedback branch is enabled. The input signal is supplied to the gain transistor 302. The gain transistor 302 amplifies the input signal and produces a current (I) at the drain with a gain corresponding to the device transconductance (gm). However, because the RC feedback branch is enabled, a portion of the current I is supplied as feedback through the RC feedback branch 310 to the input. A portion of the current is also provided to the cascode transistor 304 to produce an output at the output node OUT.

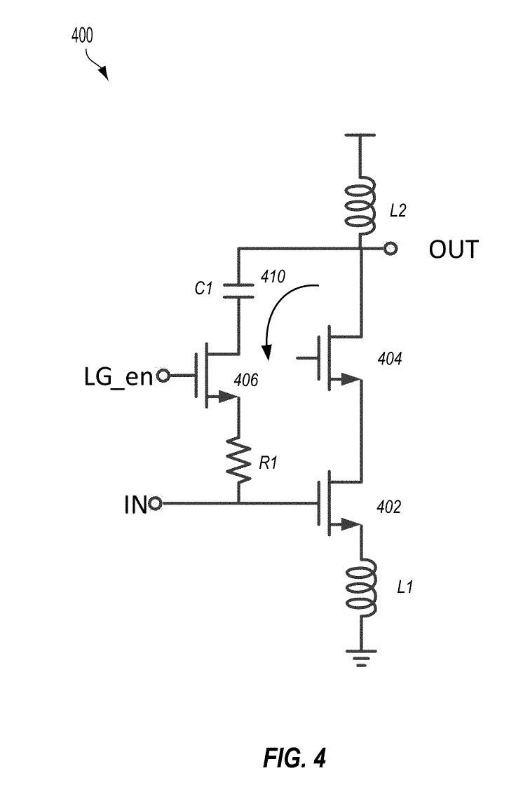

FIG. 4 is a schematic diagram of an exemplary LNA 400 in accordance with aspects of the present disclosure. The LNA 400 includes a gain transistor 402, a cascode transistor 404 and an RC feedback branch 410. The RC feedback branch 410 includes a feedback transistor 406 (which may also be referred to as “switch 410”) coupled between a resistor R1 and a capacitor C1. In this exemplary LNA 400, the feedback transistor 406 is coupled in series with the resistor R1 and capacitor C2. The resistor R1 is coupled between an input node IN and a source of the feedback transistor 406. The capacitor C1 is coupled between the drain of feedback transistor 406 and the output node. Thus, the RC feedback branch 410 is extended around the cascode transistor 404 and is coupled between an output node OUT and the input node IN. In doing so, the loop gain T is increased in comparison to the LNA 300 of FIG. 3 and linearization is further improved. However, power consumption may be increased, while isolation may be reduced. In view of such tradeoffs, applications for the exemplary LNA 400 may include, internal LNAs of a transceiver, for example.

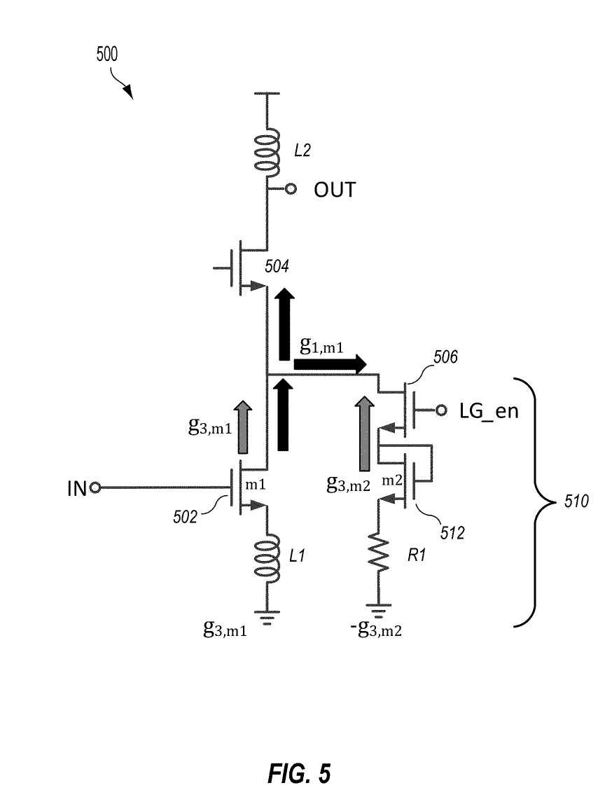

FIG. 5 is a schematic diagram of an exemplary LNA 500 with feedforward cancellation in accordance with aspects of the present disclosure. The LNA 500 includes a gain transistor 502, a cascode transistor 504 and a feedforward branch 510.

The feedforward branch 510 is coupled to the drain of the gain transistor 502 and the source of the cascode transistor 504. The gain transistor 502 has an inductor L1 coupled at the source and receives an input signal IN at the gate terminal. The drain of the cascode transistor 504 is coupled to an output terminal OUT, which is coupled to an inductor L2.

The feedforward branch 510 includes a feedforward transistor 506, a cancellation transistor 512, and a resistor R1. The cancellation transistor 512 is coupled in series between the feedforward transistor 506 and resistor R1. The cancellation transistor 512 may comprise a diode connected device. That is, the cancellation transistor has a diode connection between the gate and the drain. Resistor R1 is coupled to the source of the cancellation transistor 512.

The feedforward transistor 506 receives a control signal LG_en, which may be used to enable or disable the feedforward branch. The third order transconductance of the cancellation transistor 512 (g3,m2) may be matched or equivalent to the third order transconductance of the gain transistor 502 (g3,m1).

In some aspects, the feedforward branch 510 may be enabled or disabled based on the mode of operation of the LNA 500. For example, in high gain (sensitivity) mode, the feedforward branch 510 may be disabled (feedforward transistor 506 is controlled to be OFF). On the other hand, in low gain mode, the feedforward branch 510 may be enabled (feedforward transistor 506 is controlled to be ON).

In high gain mode operation, the LNA 500 may receive an input signal (e.g., a voltage) at an input node IN. In this mode, the linearity may not be a significant factor, so the LNA 500 may be operated without the feedforward branch 510. The control signal LG_en may control the feedback transistor to be OFF, thus disabling the feedforward branch 510. The input signal is supplied to the gain transistor 502. The gain transistor 502 amplifies the input signal and produces a current (I) at the drain with a gain corresponding to the device transconductance (gm). This current I is provided to the cascode transistor 304 and output via an output node OUT.

On the other hand, in low gain mode operation, the LNA 500 may receive an input signal (e.g., a voltage) at the input node IN. In this mode, the linearity may be a more significant factor, so the LNA 500 may be operated with the feedforward branch 510. The control signal LG_en may control the feedback transistor to be ON, thus enabling the feedforward branch 510. The input signal is supplied to the gate of the gain transistor 502. The gain transistor 502 amplifies the input signal and produces a current (I) at the drain with a gain corresponding to the device transconductance (gm). The gain transistor 502 produces a nonlinear term (third order transconductance (g3,m1)). When the feedforward branch is enabled, the cancellation transistor 512 produces a nonlinear term (third order transconductance (g3,m2)). The cancellation transistor 512 may be configured such that it produces a nonlinear term that matches that produced by the gain transistor 502. Because the nonlinear terms (third order transconductance) are matched, the nonlinear term of the cancellation transistor 512 cancels the nonlinear term of the gain transistor 502, resulting in improved linearization. Thus, the LNA 500 may be configured for feedforward cancellation for programmable low gain linearization.

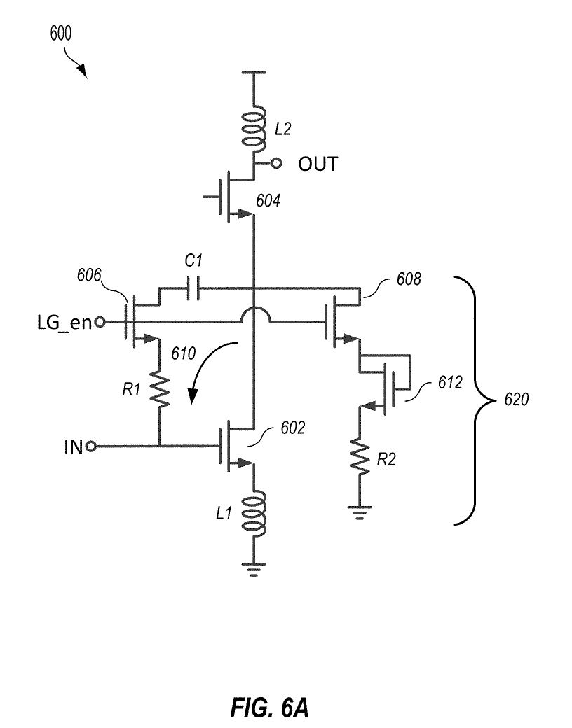

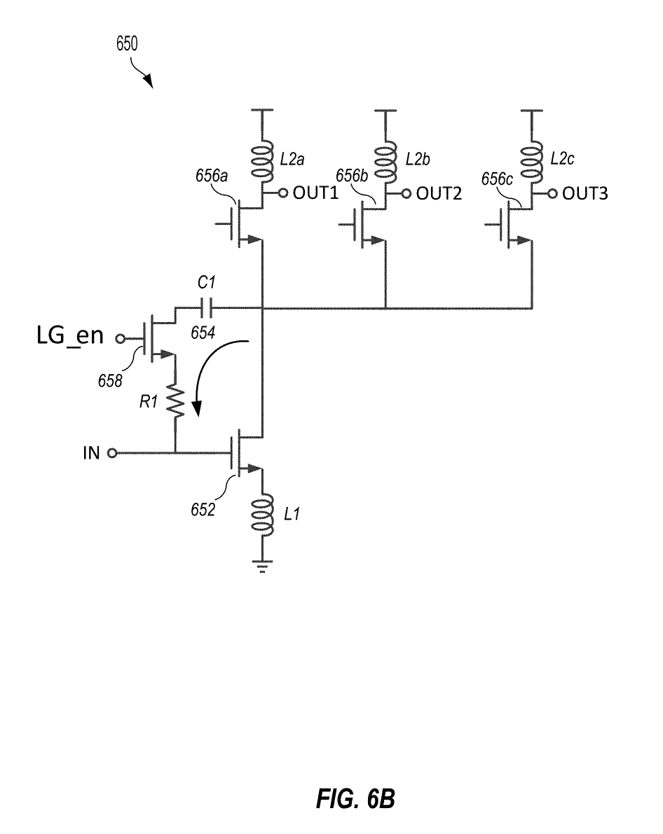

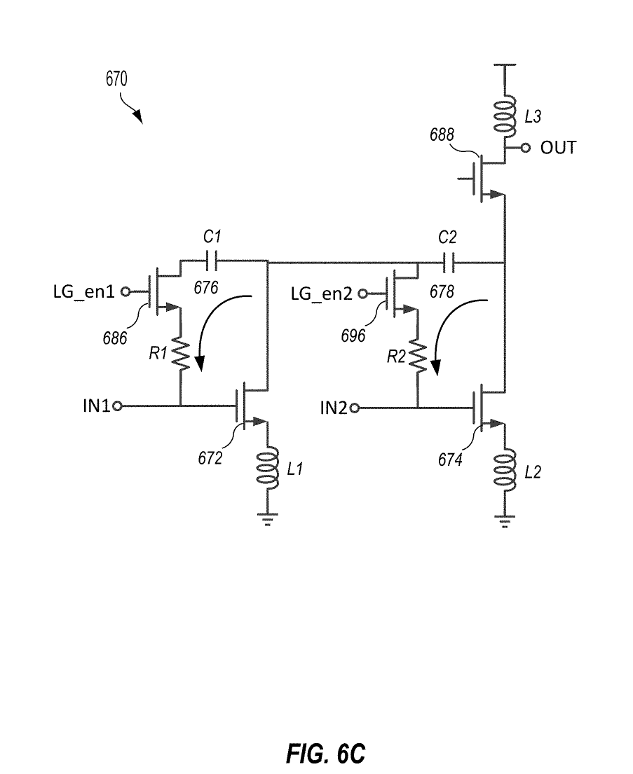

FIG. 6A is a schematic diagram of an exemplary LNA 600 with feedforward cancellation and an RC feedback branch, in accordance with aspects of the present disclosure. The LNA 600 combines the features of the RC feedback of the LNA 300 (FIG. 3) with the feedforward cancellation of the LNA 500 (FIG. 5). Referring to FIG. 6A, the LNA 600 includes a gain transistor 602, a cascode transistor 604, an RC feedback branch 610 and a feedforward branch 620. The RC feedback branch 610 includes a feedback transistor 606 coupled in series between a resistor R1 and a capacitor C1. The feedforward branch 620 includes a feedforward transistor 608, a cancellation transistor 612, and a resistor R2. The cancellation transistor 612, which may comprise a diode connected device, is coupled in series between the feedforward transistor 608 and the resistor R2.

The LNA 600 also includes an inductor L1 coupled to the source of the gain transistor 602 and an inductor L2 coupled to the drain of the cascode transistor 604. The LNA 600 further includes an input terminal IN coupled to the gate of the gain transistor 602 to receive an input signal and an output terminal OUT coupled to the drain of the cascode transistor 604 in order to output an output signal.

The RC feedback branch 610 is coupled between the gate of the gain transistor 602 and the source of the cascode transistor 604. The feedforward branch 620 is coupled between the source of the cascode transistor 604 and ground.

The feedback transistor 606 and the feedforward transistor 608 receive a control signal LG_en, which may respectively control the transistors 606 and 608 to be ON or OFF thereby enabling or disabling the feedback branch 610 and feedforward branch 620. By incorporating the RC feedback branch 610 and the feedforward branch 620, the linearity of the LNA 600 may be further improved. That is, by utilizing the RC feedback and the feedforward cancellation techniques in unison, low gain linearization may be improved.

In some aspects, transistors 606 and 608 may be enabled according to a gain mode of the LNA. For example, in low gain mode operation, the LNA 600 may receive an input signal (e.g., a voltage) at the input node IN. When the control signal LG_en controls the feedback transistor 606 and feedforward transistor 608 to be ON, the RC feedback branch 610 and the feedforward branch 620 are enabled. The input signal is supplied to the gain transistor 602. The gain transistor 602 amplifies the input signal and produces a current (I) at the drain with a gain corresponding to the device transconductance (gm). However, because the RC feedback branch 610 is enabled, a portion of the current I is supplied as feedback through the RC feedback branch 610 to the input. A portion of the current I is also provided to the cascode transistor 604 to produce an output at the output node OUT. However, because the feedforward branch is enabled, the cancellation transistor 612 produces a nonlinear term (third order transconductance (g3,m2)) that cancels the nonlinear term produced by the gain transistor 602, thus resulting in further improvement in low gain linearization.

In some aspects, the exemplary LNA 600 may further comprise multiple cascode transistors and multiple outputs. Furthermore, the exemplary LNA 600 may also include multiple inputs. Each of the multiple inputs may have a corresponding RC feedback branch. The RC feedback branch includes a feedback transistor 606 coupled in series with the resistor R1 and capacitor C1.

FIG. 6B is a schematic diagram of an exemplary LNA 650 with multiple outputs in accordance with aspects of the present disclosure. As shown in FIG. 6B, the LNA 650 has a single input IN coupled to the gate of the gain transistor 652 and an RC feedback branch 654. The RC feedback branch 654 may be configured to operate similar to the RC feedback branch 310 described above with respect to FIG. 3. The RC feedback branch 654 includes a feedback transistor 658 coupled in series with a resistor R1 and a capacitor C1. The feedback transistor 658 is controlled via a control signal LG_en. The RC feedback branch 654 is coupled between the drain of the gain transistor 652 and the gate of the gain transistor 652. The gain transistor 652 also has an inductor L1 coupled at the source terminal.

The LNA 650 includes multiple cascode transistors (e.g., 656a, 656b, 656c), multiple inductors (e.g., L1, L2a, L2b, L2c), and multiple outputs (e.g., OUT1, OUT2, and OUT3). Although three cascode transistors and outputs are shown, the present disclosure is not so limited and any number of cascode transistors and outputs may be included according to design considerations. By configuring the LNA 650 with multiple outputs, the LNA 650 may beneficially provide additional support for a variety of applications including carrier aggregation, for example.

FIG. 6C is a schematic diagram of an exemplary LNA 670 with multiple inputs in accordance with aspects of the present disclosure. As shown in FIG. 6C, the LNA 670 has a multiple inputs IN1 and IN2, which are respectively coupled to the gates of the gain transistors 672 and 674, as well as a single output OUT. Although two inputs are shown, this is merely exemplary and not limiting. Rather, any number of inputs may be included according to design preference. The inductors L1 and L2 are coupled to the sources of the gain transistors 672 and 674, respectively. A cascode transistor 688 and inductor L3 are coupled to the output OUT. Each of the inputs has a corresponding RC feedback branch (e.g., 676 and 678) as described above with respect to FIG. 3. Each RC feedback branch (e.g., 676 and 678) is coupled between the gate and the drain of the corresponding gain transistor (e.g., 672, 674) and includes a capacitor (e.g., C1, C2), a resistor (e.g., R1, R2), and a feedback transistor (e.g., 686, 696) controlled by signals LG_en1 and LG_en2. In some aspects, the LNA 670 with multiple inputs may be configured as an artificially wideband LNA in which each input receives a signal within a different narrow band, for example.

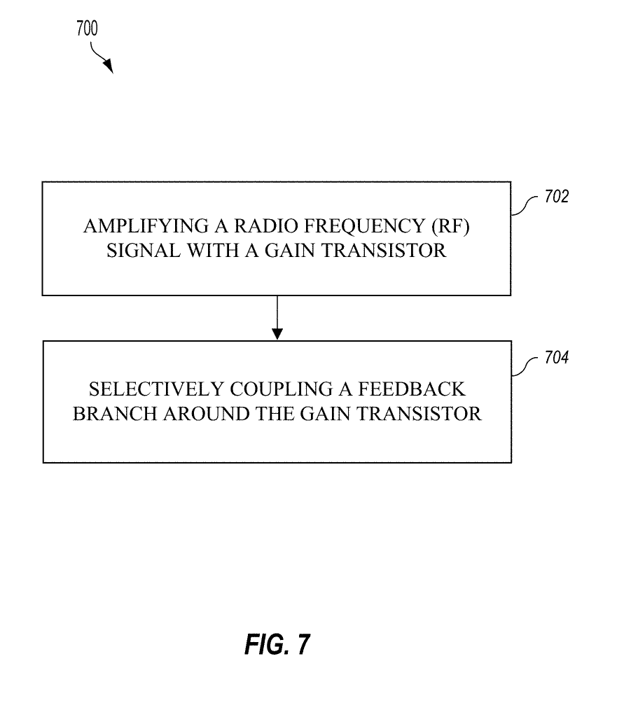

FIG. 7 is a flow diagram illustrating an exemplary method 700 in accordance with aspects of the present disclosure. In block 702, the process amplifies a radio frequency (RF) input signal with a gain transistor to produce an amplified signal. In block 704, the process selectively couples a feedback branch around the gain transistor. The feedback branch is coupled between the drain of a cascode transistor or the drain of the gain transistor and the gate of the gain transistor. In some aspects, the feedback branch may comprise a resistor and a capacitor. For example, as shown in FIG. 3, the LNA 300 has a feedback branch that includes a resistor R1 and capacitor C1, which are coupled in series with the feedback transistor 306. The capacitor is selectively coupled to the drain of the gain transistor and the resistor is selectively coupled to the gate of the gain transistor under the control of a switch (e.g., feedback transistor 306). The feedback branch may be selectively coupled around the gain transistor based on the mode of operation. For instance, the feedback branch may be coupled around the gain transistor during operation in a low gain mode.

In some aspects, the process may further comprise selectively cancelling a nonlinear tone of the gain transistor. For example, as shown in FIG. 5 a feedforward branch 510 is selectively coupled to the drain of the gain transistor 502 via the cancellation transistor 512. The feedforward branch includes a second transistor and a resistor. The second transistor has a third order transconductance that matches a third order transconductance of the gain transistor 502.

According to aspects of the present disclosure, an LNA is described. The LNA includes means for amplifying a radio frequency signal. The means for amplifying may, for example, include the gain transistor 302, gain transistor 402, gain transistor 502, or gain transistor 602, 652, 672 as shown in FIGS. 3-6C, respectively. The LNA may also include means for selectively coupling a feedback branch around the amplifying means. The means for selectively coupling may, for example, include the feedback transistor 306, feedback transistor 406, or feedback transistor 606, 658, 686, 696 of FIGS. 3, 4, and 6C, respectively. In another aspect, the aforementioned means may be any layer, module, or any apparatus configured to perform the functions recited by the aforementioned means.

The disclosed amplifiers with low gain linearization for high SNR may be implemented on an IC, an analog IC, an RFIC, a mixed-signal IC, an ASIC, a printed circuit board (PCB), an electronic device, etc. The amplifiers may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing an amplifier with low gain linearization for high SNR disclosed herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

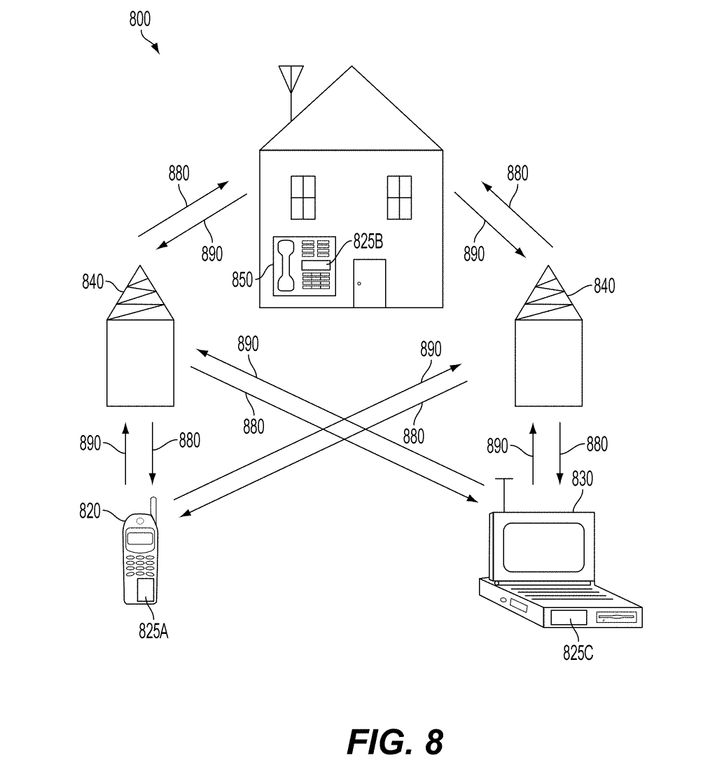

FIG. 8 is a block diagram showing an exemplary wireless communication system 800 in which an aspect of the disclosure may be advantageously employed. For purposes of illustration, FIG. 8 shows three remote units 820, 830, and 850 and two base stations 940. It will be recognized that wireless communication systems may have many more remote units and base stations. Remote units 820, 830, and 850 include IC devices 825A, 825C, and 825B that include the disclosed low noise amplifier. It will be recognized that other devices may also include the disclosed low noise amplifier, such as the base stations, user equipment, and network equipment. FIG. 8 shows forward link signals 880 from the base station 840 to the remote units 820, 830, and 850 and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the disclosed low noise amplifier.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communication networks and/or communication technologies. The apparatuses, methods, and systems disclosed herein may also be implemented digitally and differentially, among others. The various components illustrated in the figures may be implemented as, for example, but not limited to, software and/or firmware on a processor, ASIC/FPGA/DSP, or dedicated hardware. Also, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

Although the present disclosure provides certain example aspects and applications, other aspects that are apparent to those of ordinary skill in the art, including aspects which do not provide all of the features and advantages set forth herein, are also within the scope of this disclosure. For example, the apparatuses, methods, and systems described herein may be performed digitally and differentially, among others. Accordingly, the scope of the present disclosure is intended to be defined only by reference to the appended claims.

1. A low noise amplifier (LNA) comprising:
a transconductance device coupled to a cascode transistor; and
a resistor capacitor (RC) feedback branch comprising a first resistor, a capacitor and a first switch fed back around the transconductance device, the RC feedback branch being coupled between a drain of the cascode and a gate of the transconductance device or coupled between the gate of the transconductance device and a node between a source of the cascode transistor and a drain of the transconductance device.

2. The LNA of claim 1, in which the RC feedback branch feeds back around the cascode transistor.

3. The LNA of claim 1, in which the RC feedback branch feeds back around the transconductance device.

4. The LNA of claim 1, further comprising a feedforward branch coupled to the drain of the transconductance device via a second switch, the feedforward branch including a diode connected device and a second resistor coupling a source terminal of the diode connected device to ground, a drain of the diode connected device coupled to the second switch.

5. The LNA of claim 1, in which the RC feedback branch receives input from an output of the LNA.

6. The LNA of claim 1 further comprising a plurality of cascode transistors and a plurality of outputs.

7. The LNA of claim 1, further comprising a plurality of inputs, each input of the plurality of inputs having a corresponding RC feedback branch.

8. A method comprising:
amplifying a radio frequency (RF) input signal with a gain transistor to produce an amplified signal; and
selectively coupling a feedback branch around the gain transistor, the feedback branch being coupled between a drain of a cascode transistor and a gate of the gain transistor or coupled between the gate of the gain transistor and a node between a source of the cascode transistor and a drain of the gain transistor.

9. The method of claim 8, in which the selectively coupling is based at least in part on a mode of operation.

10. The method of claim 9, in which the mode of operation comprises a low gain mode.

11. The method of claim 8, in which the feedback branch comprises a resistor and a capacitor, the capacitor being selectively coupled to the drain of the gain transistor and the resistor being selectively coupled to the gate of the gain transistor.

12. The method of claim 8, further comprising:
supplying the amplified signal to the cascode transistor to generate an output signal, and
in which the feedback branch comprises a resistor and a capacitor, the capacitor being selectively coupled to the drain of the cascode transistor and the resistor being selectively coupled to the gate of the gain transistor.

13. The method of claim 8, further comprising selectively cancelling a first nonlinear tone of the gain transistor.

14. The method of claim 13, in which the selectively cancelling comprises selectively coupling a feedforward branch comprising a second transistor and a resistor to the drain of the gain transistor, the feedforward branch generating a second nonlinear tone to cancel the first nonlinear tone of the gain transistor.

15. The method of claim 14, in which the second transistor has a third order transconductance matching a third order transconductance of the gain transistor.

16. A low noise amplifier (LNA), comprising:
means for amplifying a radio frequency (RF) input signal to produce an amplified signal;
means for selectively coupling a feedback branch around the amplifying means, the feedback branch coupled between a drain of a first device and a gate of the amplifying means; and
means for selectively cancelling a first nonlinear tone of the amplifying means by selectively coupling a feedforward branch to the drain of the amplifying means, the feedforward branch generating a second nonlinear tone to cancel the first nonlinear tone.

17. The LNA of claim 16, in which the first device comprises a cascode transistor or the amplifying means.

18. The LNA of claim 16, in which the feedback branch is selectively coupled around the amplifying means in a low gain mode of operation.

19. (canceled)

20. (canceled)

21. A low noise amplifier (LNA) comprising:
a transconductance device coupled to a cascode transistor;
a resistor capacitor (RC) feedback branch comprising a first resistor, a capacitor and a first switch fed back around the transconductance device, the RC feedback branch being coupled between a drain of either the cascode transistor or the transconductance device and a gate of the transconductance device; and
a feedforward branch coupled to the drain of the transconductance device via a second switch, the feedforward branch including a diode connected device and a second resistor coupling a source terminal of the diode connected device to ground, a drain of the diode connected device coupled to the second switch.

22. A method comprising:
amplifying a radio frequency (RF) input signal with a gain transistor to produce an amplified signal;
selectively coupling a feedback branch around the gain transistor, the feedback branch being coupled between either a drain of a cascode transistor or the gain transistor and a gate of the gain transistor; and
selectively cancelling a first nonlinear tone of the gain transistor by selectively coupling a feedforward branch comprising a second transistor and a resistor to the drain of the gain transistor, the feedforward branch generating a second nonlinear tone to cancel the first nonlinear tone of the gain transistor.
